(19) United States
(12) Patent Application Publication
(10) Pub. No.: US 2026/0094554 A1
(43) Pub. Date: Apr. 2, 2026

(54) DISPLAY DEVICE UPDATING IMAGE PROCESSING ALGORITHM AND CONTROL METHOD THEREOF

(71) Applicant: SAMSUNG ELECTRONICS CO., LTD., Suwon-si (KR)

(72) Inventor: Dongik LEE, Suwon-si (KR)

(73) Assignee: SAMSUNG ELECTRONICS CO., LTD., Suwon-si (KR)

(21) Appl. No.: 19/413,442

(22) Filed: Dec. 9, 2025

Related U.S. Application Data
(63) Continuation of application No. PCT/KR2024/008928, filed on Jun. 27, 2024.

(30) Foreign Application Priority Data
Aug. 22, 2023 (KR) 10-2023-0109951

(51) Int. Cl. G09G 3/20; H03G 3/30

(52) U.S. Cl. CPC G09G 3/2003; H03G 3/3089; G09G 2320/0646

(57) ABSTRACT

A display device includes: a communication interface; a display; memory storing instructions; and at least one processor, wherein the instructions, when executed by the at least one processor individually or collectively, cause the display device to: based on receiving an image signal, obtain a screen corresponding to the image signal by using an image processing algorithm, identify a grayscale ratio within the screen, based on the grayscale ratio being greater than or equal to a threshold, update the image processing algorithm, reobtain a screen corresponding to the image signal by using the updated image processing algorithm, control the display to output the reobtained screen, and based on the grayscale ratio within the screen being greater than or equal to the threshold, control the communication interface to transmit log information including state information of the display device to an external device.

### CROSS-REFERENCE TO RELATED APPLICATIONS

This application is a continuation application of International Patent Application No. PCT/KR2024/008928, filed on June 27, 2024, which is based on and claims priority to Korean Patent Application No. 10-2023-0109951, filed on August 22, 2023, the disclosures of which are incorporated by reference herein in their entireties.

### BACKGROUND

### Field

The present disclosure relate to a display device and a control method thereof, and more particularly, to a display device that identifies whether to update an image processing algorithm, and a control method thereof.

### Description of Related Art

Recently, various home appliances are being developed and distributed, and in particular, development and distribution of display devices, source devices, etc. are more active than any other fields.

A display device that is recently being distributed can provide various functions other than a function of just outputting a screen. For example, a display device may perform various functions such as SNS, web surfing, OTT access, games, etc. by accessing the Internet and installing applications.

As a display device provides various functions, causes of errors are becoming diverse and complex, and there is a disadvantage that the time required for repairing a device also increases. For example, it is difficult to reproduce a situation wherein an error occurs for identifying a cause of the error, and it is also difficult to identify the state of a device when an error occurs.

For resolving the aforementioned problems, there has been a demand for a method for a device to identify whether an error occurred and repair the error by itself, and a method for storing the state of a device when an error occurs and easily reproducing the state later.

### SUMMARY

According to an aspect of the disclosure, a display device includes: a communication interface; a display; memory storing instructions; and at least one processor, wherein the instructions, when executed by the at least one processor individually or collectively, cause the display device to: based on receiving an image signal, obtain a screen corresponding to the image signal by using an image processing algorithm, identify a grayscale ratio within the screen, based on the grayscale ratio being greater than or equal to a threshold, update the image processing algorithm, reobtain a screen corresponding to the image signal by using the updated image processing algorithm, control the display to output the reobtained screen, and based on the grayscale ratio within the screen being greater than or equal to the threshold, control the communication interface to transmit log information including state information of the display device to an external device.

The instructions, when executed by the at least one processor individually or collectively, cause the display device to: based on the grayscale ratio being greater than or equal to the threshold, identify whether update was performed based on version information of the image processing algorithm, and reobtain the screen in which the grayscale ratio was adjusted by using the updated image processing algorithm.

The instructions, when executed by the at least one processor individually or collectively, may cause the display device to: reobtain the screen in which at least one of color balance, brightness, contrast, or white balance was adjusted by using the updated image processing algorithm.

The log information includes a number of times that the grayscale ratio of the screen is identified to be greater than or equal to the threshold, and the state information includes at least one of the image signal, version information of the image processing algorithm, or a set value related to image output of the display device.

The instructions, when executed by the at least one processor individually or collectively, may cause the display device to: obtain, using the image processing algorithm, the screen corresponding to the image signal by converting a color format of the image signal into an RGB signal; and reobtain, using the updated image processing algorithm, the screen corresponding to the image signal by converting the color format of the image signal into a YCbCr signal.

The instructions, when executed by the at least one processor individually or collectively, may cause the display device to: obtain, using the image processing algorithm, the screen corresponding to the image signal by converting a color format of the image signal into a YCbCr signal; and reobtain, using the updated image processing algorithm, the screen corresponding to the image signal by converting the color format of the image signal into an RGB signal.

The display device may further include: a speaker; and a microphone, wherein the instructions, when executed by the at least one processor individually or collectively, may cause the display device to: based on the image signal including an audio signal, output a sound corresponding to the audio signal through the speaker; and identify whether the sound was received through the microphone.

The instructions, when executed by the at least one processor individually or collectively, may cause the display device to: based on the sound not being received through the microphone, adjust a gain value of the speaker; and re-output the sound corresponding to the audio signal through the microphone in which the gain value was adjusted.

The instructions, when executed by the at least one processor individually or collectively, may cause the display device to: receive a loopback signal according to the output of the sound through the speaker; and based on a size value of the sound not being identified based on the loopback signal, adjust a gain value of the speaker.

The instructions, when executed by the at least one processor individually or collectively, may cause the display device to: based on the sound not being received through the microphone, transmit the log information including the state information of the display device to the external device, the log information includes a number of times of outputting the sound that was not received through the microphone, and the state information includes at least one of the audio signal, a gain value of the speaker, or a set value related to sound output of the display device.

According to an aspect of the disclosure, a method of controlling a display device, includes: based on receiving an image signal, obtaining a screen corresponding to the image signal by using an image processing algorithm; identifying a grayscale ratio within the screen; based on the grayscale ratio being greater than or equal to a threshold, updating the image processing algorithm; reobtaining a screen corresponding to the image signal by using the updated image processing algorithm; outputting the reobtained screen; and based on the grayscale ratio within the screen being greater than or equal to the threshold, transmitting log information including state information of the display device to an external device.

The updating may include, based on the grayscale ratio being greater than or equal to the threshold, identifying whether update was performed based on version information of the image processing algorithm, and the reobtaining includes reobtaining the screen in which the grayscale ratio was adjusted using the updated image processing algorithm.

The reobtaining may include reobtaining the screen in which at least one of color balance, brightness, contrast, or white balance was adjusted using the updated image processing algorithm.

The log information may include a number of times that the grayscale ratio of the screen is identified to be greater than or equal to the threshold, and the state information includes at least one of the image signal, version information of the image processing algorithm, or a set value related to image output of the display device.

The obtaining may include obtaining, using the image processing algorithm, the screen corresponding to the image signal by converting a color format of the image signal into an RGB signal; and the reobtaining may include, using the updated image processing algorithm, reobtaining the screen corresponding to the image signal by converting the color format of the image signal into a YCbCr signal.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a diagram for illustrating a display device according to one or more embodiments of the present disclosure;

FIG. 2 is a block diagram illustrating a configuration of a display device according to one or more embodiments of the present disclosure;

FIG. 3 is a diagram for illustrating a normal screen and an abnormal screen according to one or more embodiments of the present disclosure;

FIG. 4 is a diagram for illustrating a grayscale ratio according to an image processing algorithm according to one or more embodiments of the present disclosure;

FIG. 5 is a diagram for illustrating a grayscale ratio according to an image processing algorithm according to one or more embodiments of the present disclosure;

FIG. 6 is a flow chart for illustrating a control method of a display device updating an image processing algorithm according to one or more embodiments of the present disclosure;

FIG. 7 is a diagram for illustrating a display device outputting a sound according to one or more embodiments of the present disclosure;

FIG. 8 is a flow chart for illustrating a control method of a display device adjusting a gain of a speaker according to one or more embodiments of the present disclosure; and

FIG. 9 is a flow chart for illustrating a control method of a display device according to one or more embodiments of the present disclosure.

### DETAILED DESCRIPTION

Hereinafter, embodiments of the present disclosure will be described in detail with reference to the accompanying drawings.

As terms used in one or more embodiments of the present disclosure, general terms that are currently used widely were selected as far as possible, in consideration of the functions described in the present disclosure. However, the terms may vary depending on the intention of those skilled in the art, previous court decisions, or emergence of new technologies, etc. Also, in particular cases, there may be terms that were arbitrarily designated by the applicant, and in such cases, the meaning of the terms will be described in detail in the relevant descriptions in the present disclosure. Accordingly, the terms used in the present disclosure should be defined based on the meaning of the terms and the overall content of the present disclosure, but not just based on the names of the terms.

Terms such as “comprising,” “having,” “including,” and “containing” are to be construed as open-ended terms (meaning “including, but not limited to,”) unless otherwise noted. The terms may specify the presence of stated features, numbers, steps, operations, elements, components or combinations thereof. The terms may not preclude the possibility of the presence or addition of one or more other features, numbers, steps, operations, elements, components, and/or combinations thereof. Recitation of ranges of values herein are merely intended to serve as a shorthand method of referring individually to each separate value falling within range, unless otherwise indicated herein and each separate value is incorporated into specification as if it were individually recited herein.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present.

Further, the expressions such as “first,” “second,” and the like used in this specification may be used to describe various elements regardless of any order and/or degree of importance. Also, such expressions are used only to distinguish one element from another element, and are not intended to limit the elements.

Meanwhile, the description in the disclosure that one element (e.g., a first element) is “(operatively or communicatively) coupled with/to” or “connected to” another element (e.g., a second element) should be interpreted to include both the case where the one element is directly coupled to the another element, and the case where the one element is coupled to the another element through still another element (e.g., a third element).

Also, singular expressions include plural expressions, unless defined obviously differently in the context.

Unless explicitly described or implicitly understood from one or more embodiments of the present disclosure, at least one of the components, elements, modules or units, or any nominalized verbs (collectively "components" in this paragraph) represented by a block or an equivalent indication in the drawings may be implemented or embodied by analog and/or digital circuits including one or more of a logic gate, an integrated circuit, a microprocessor, a microcontroller, a memory circuit, a passive electronic component, an active electronic component, an optical component, and the like. Alternatively or additionally, these components may be implemented or embodied by software including one or more instructions stored in an internal or external storage medium that is readable by at least one processor. For example, the at least one processor may invoke at least one of the one or more instructions stored in the storage medium, and execute it, with or without using one or more other components under the control of the at least one processor. This allows the at least one processor to perform at least one function or operation described above as being performed by each of the components according to the at least one instruction invoked. Here, the at least one processor may include a central processing unit (CPU), a graphic processing unit (GPU), another type of microprocessor, not being limited thereto. In other examples, the at least one processor may be implemented in application specific integrated circuit (ASIC) and field-programmable gate array (FPGA).

Also, in this specification, the term “user” may refer to a person who uses an electronic apparatus or an apparatus using an electronic apparatus (e.g.: an artificial intelligence electronic apparatus).

Hereinafter, embodiments of the disclosure will be described in more detail with reference to the accompanying drawings.

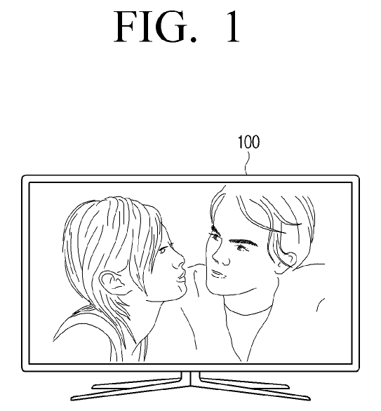

FIG. 1 is an example diagram for illustrating a display device according to one or more embodiments of the disclosure.

Referring to FIG. 1, a display device 100 according to one or more embodiments of the disclosure may display a content. The display device 100 may be implemented as a TV, but is not limited thereto, and any device equipped with a display function such as a video wall, a large format display (LFD), digital signage, a digital information display (DID), a projector display, etc. can be applied without limitation. Also, the display device 100 may include displays in various forms such as a liquid crystal display (LCD), organic light-emitting diodes (OLED), liquid crystal on silicon (LCoS), digital light processing (DLP), a quantum dot (QD) display panel, quantum dot light-emitting diodes (QLED), etc.

However, one or more embodiments of the present disclosure is not limited thereto, and the display device 100 may be implemented as output devices in various forms. For example, the display device 100 can obviously be implemented as a user terminal device, or an audio output device (e.g., a sound bar, a home theater system, a room speaker, a headphone, earphones, etc.).

The display device 100 according to one or more embodiments may receive an image signal (or, a content) from a source device, and output the received image signal. Here, the image signal includes a video signal, an audio signal, etc., and hereinafter, explanation will be described by assuming a case in which the display device 100 displays an image signal received from a source device, for the convenience of explanation.

The source device according to one or more embodiments may be implemented as an electronic apparatus such as a set-top box, a cloud server, an over-the-top (OTT) media service server, a streaming service (e.g., Samsung Gaming Hub), a home automation control panel, a security control panel, a media box (e.g.: Samsung HomeSync^{TM}, Apple TV^{TM}, or Google TV^{TM}), a game console (e.g.: Xbox^{TM}, PlayStation^{TM}, Switch^{TM}), an electronic dictionary, an electronic key, a camcorder, or an electronic photo frame. However, one or more embodiments of the present disclosure is not limited thereto, and the source device may include at least one of a TV, a user terminal device, a tablet PC, a mobile phone, a video phone, an e-book reader, a desktop PC, a laptop PC, a netbook computer, a workstation, a server, a PDA, a portable multimedia player (PMP), an MP3 player, a medical device, a camera, a virtual reality (VR) implementation device, or a wearable device. Here, a wearable device can obviously be implemented as at least one of an accessory-type device (e.g.: a watch, a ring, a bracelet, an ankle bracelet, a necklace, glasses, a contact lens, or a head-mounted-device (HMD)), a device integrated with fabrics or clothing (e.g.: electronic clothing), a body-attached device (e.g.: a skin pad or a tattoo), or an implantable circuit.

The display device 100 according to one or more embodiments may, if an image signal is received, obtain and display a screen corresponding to the image signal by using an image processing algorithm.

According to one or more embodiments, distortion may be generated in color components of an image signal due to a state of a connecting cable between the display device 100 and a source device, an external noise received together with the image signal, an error in an image processing algorithm, etc. For example, if an error is generated in a gray component of an image signal, a screen corresponding to the image signal may include a red color on the whole (e.g., a pinkish screen), or include a blue color (e.g., a greenish screen), and the display device 100 may display the distorted screen.

According to one or more embodiments, the display device 100 may identify whether distortion is generated by analyzing a screen to be displayed by itself, and if distortion is generated, the display device 100 may update the image processing algorithm and obtain and display a screen in which distortion was not generated.

Also, for reproducing generation of distortion easily at the time of repair of the display device 100, the display device 100 may obtain log information including state information of the display device 100 when distortion was generated, and transmit the log information to an external device (e.g., a server).

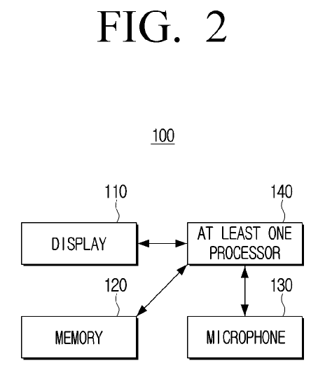

FIG. 2 is a block diagram illustrating a configuration of a display device according to one or more embodiments of the present disclosure.

According to FIG. 2, the display device 100 may include a display 110, memory 120, a communication interface 130, and at least one processor 140.

The display 110 according to one or more embodiments of the present disclosure may be implemented as displays in various forms such as a liquid crystal display (LCD), organic light-emitting diodes (OLED), liquid crystal on silicon (LCoS), digital light processing (DLP), a quantum dot (QD) display panel, quantum dot light-emitting diodes (QLED), micro light-emitting diodes (μLED), mini LED, etc. Meanwhile, the display 110 may also be implemented as a touch screen combined with a touch sensor, a flexible display, a rollable display, a 3D display, a display to which a plurality of display modules are physically connected, etc.

The memory 120 according to one or more embodiments may store data necessary for the various embodiments of the present disclosure. The memory 120 may be implemented in a form of memory embedded in the display device 100, or implemented in a form of memory that can be attached to or detached from the display device 100 according to the use of stored data.

For example, data for driving the display device 100 may be stored in memory embedded in the display device 100, and data for an extended function of the display device 100 may be stored in memory that can be attached to or detached from the display device 100. Meanwhile, in the case of memory embedded in the display device 100, the memory may be implemented as at least one of volatile memory (e.g.: dynamic RAM (DRAM), static RAM (SRAM), or synchronous dynamic RAM (SDRAM), etc.) or non-volatile memory (e.g.: one time programmable ROM (OTPROM), programmable ROM (PROM), erasable and programmable ROM (EPROM), electrically erasable and programmable ROM (EEPROM), mask ROM, flash ROM, flash memory (e.g.: NAND flash or NOR flash, etc.), a hard drive, or a solid state drive (SSD)). Also, in the case of memory that can be attached to or detached from the display device 100, the memory may be implemented in forms such as a memory card (e.g., compact flash (CF), secure digital (SD), micro secure digital (Micro-SD), mini secure digital (Mini-SD), extreme digital (xD), a multi-media card (MMC), etc.), and external memory that can be connected to a USB port (e.g., USB memory), etc.

According to one or more embodiments, the memory 120 may store at least one instruction or a computer program including instructions that are executed by the at least one processor 140 for controlling the display device 100. In particular, the memory 120 may store an image processing algorithm for obtaining a screen corresponding to an image signal by processing the image signal.

The communication interface 130 according to one or more embodiments may include wired or wireless input/output interfaces (or, input/output terminals) according to various specifications. For example, the communication interface 130 may include various interfaces such as a high-definition multimedia interface (HDMI), a mobile high-definition link (MHL), a universal serial bus (USB), a display port (DP), Thunderbolt, a video graphics array (VGA) port, an RGB port, a D-subminiature (D-SUB), a digital visual interface (DVI), Wi-Fi based on AP (Wi-Fi, a wireless LAN network), Bluetooth, Zigbee, a wired/wireless local area network (LAN), a wide area network (WAN), Ethernet, IEEE 1394, AES/EBU (Audio Engineering Society/European Broadcasting Union), Optical, Coaxial, etc.

In particular, the communication interface 130 may receive an image signal from a source device, and transmit log information to an external device (e.g., a server) according to control by the at least one processor 140.

The at least one processor 140 according to one or more embodiments may control overall operations of the display device 100.

According to one or more embodiments of the present disclosure, the at least one processor 140 may be implemented as a digital signal processor (DSP) processing digital signals, a microprocessor, and a timing controller (TCON). However, the present disclosure is not limited thereto, and the at least one processor 140 may include one or more of a central processing unit (CPU), a micro controller unit (MCU), a micro processing unit (MPU), a controller, an application processor (AP) or a communication processor (CP), an ARM processor, and an artificial intelligence (AI) processor, or may be defined by the terms. Also, the at least one processor 140 may be implemented as a system on chip (SoC) having a processing algorithm stored therein or large scale integration (LSI), or in the form of a field programmable gate array (FPGA). The at least one processor 140 may perform various functions by executing computer executable instructions stored in the memory.

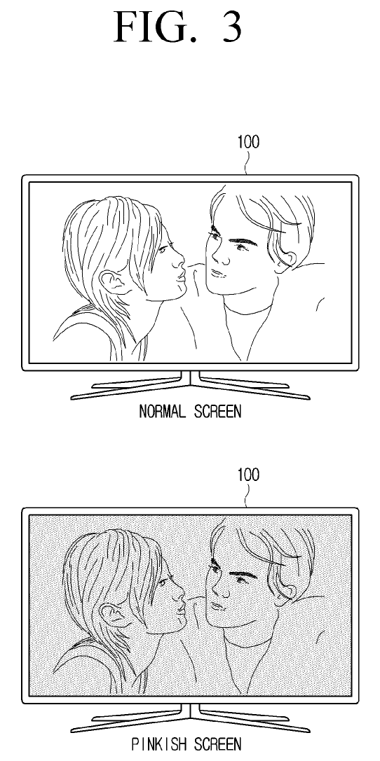

FIG. 3 is a diagram for illustrating a normal screen and an abnormal screen according to one or more embodiments of the present disclosure.

The at least one processor 140 according to one or more embodiments may, if an image signal is received, obtain a screen corresponding to the image signal by using an image processing algorithm. The at least one processor 140 according to one or more embodiments may identify a grayscale ratio (e.g., percentage of grayscale content, how much of an image consists of grayscale) within the screen.

For example, if an image signal is received, the at least one processor 140 may analyze pixel values according to the image signal and identify a gray level (e.g., a gray tone) of the input image.

According to one or more embodiments, the at least one processor 140 may change the color temperature of the gray level, and if the color temperature (e.g., white balance) of the gray level is changed, the color temperature of the screen corresponding to the image signal may be changed.

According to one or more embodiments, if the grayscale ratio within the screen is greater than or equal to a threshold, the at least one processor 140 may identify the screen as an abnormal screen, but not a normal screen corresponding to the image signal.

For example, the at least one processor 140 may capture the screen corresponding to the image signal and obtain a capture image, and identify whether the grayscale ratio within the capture image is greater than or equal to the threshold (e.g., threshold scale). For example, the at least one processor 140 may identify whether the grayscale ratio within the capture image is greater than or equal to 18% (or, 20%). Meanwhile, the specific numbers are merely examples for the convenience of explanation, and the present disclosure is not limited thereto.

According to one or more embodiments, if the grayscale ratio within the capture image is greater than or equal to the threshold, the capture image may include a red color (or, a violet color) on the whole, or include a cyanic color (or, a blue color). For example, if the color temperature of the capture image is lower than 3000K, the capture image may show a reddish color on the whole, and if the color temperature is higher than or equal to 7000K, the capture image shows a bluish color on the whole.

For example, if the image processing algorithm wrongly recognizes a color space of pixel values according to an image signal, a grayscale ratio within the screen corresponding to the image signal that the at least one processor 140 obtained by using the image processing algorithm may be greater than or equal to the threshold (e.g., 18%). According to one or more embodiments, the at least one processor 140 may identify the screen as an abnormal screen (e.g., not a normal screen) corresponding to the image signal.

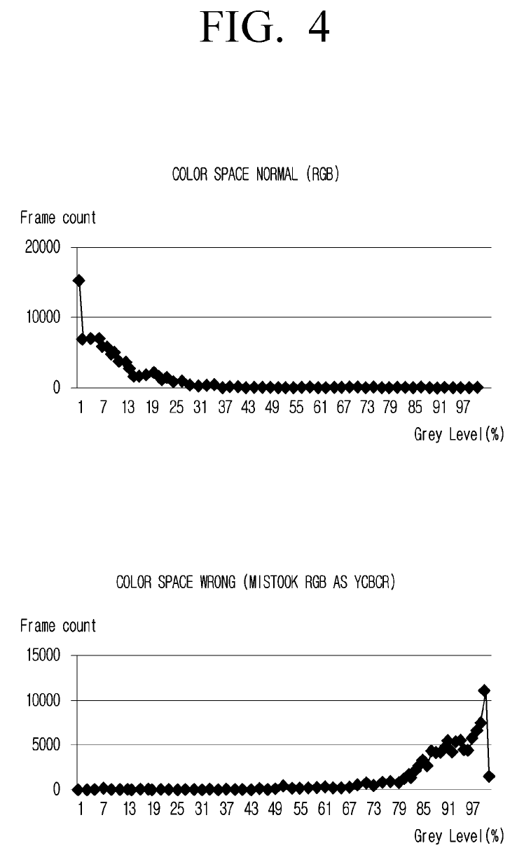

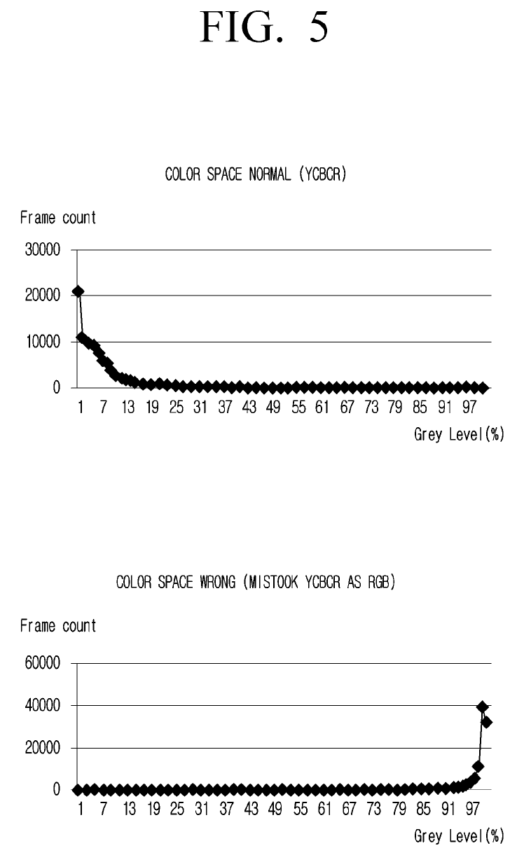

Detailed explanation in this regard will be described with reference to FIG. 4 and FIG. 5.

FIG. 4 is a diagram for illustrating a grayscale ratio according to an image processing algorithm according to one or more embodiments of the present disclosure.

Referring to FIG. 4, according to one or more embodiments, a color space is a space expressing colors, and may include various methods such as RGB, CMYK, HSV, CIE, YUV (e.g., YCbCr), etc.

According to one or more embodiments, an image processing algorithm may recognize a color space of an image signal as RGB, and obtain a screen corresponding to the image signal including an RGB signal.

According to one or more embodiments, if the image signal includes an RGB signal, a screen that the at least one processor 140 obtained by converting the color format of the image signal into an RGB signal by using the image processing algorithm may be a normal screen.

As illustrated in the upper graph in FIG. 4, the image signal may include a plurality of image frames, and if the image processing algorithm recognizes a color space of the image signal appropriately, the grayscale ratios of each of the plurality of image frames included in the image signal may be smaller than the threshold.

According to another embodiment, the image processing algorithm may recognize a color space of an image signal as YCbCr, and obtain a screen corresponding to the image signal including a YCbCr signal.

For example, if the image signal includes an RGB signal, a screen that the at least one processor 140 obtained by converting the color format of the image signal into a YCbCr signal by using the image processing algorithm may be an abnormal screen. As illustrated in the lower graph in FIG. 4, if the image processing algorithm cannot recognize a color space of the image signal appropriately, the grayscale ratios of each of the plurality of image frames may be greater than or equal to the threshold.

According to one or more embodiments, if image frames in which grayscale ratios are greater than or equal to the threshold are identified in greater than or equal to a threshold number among a plurality of image frames included in an image signal, the at least one processor 140 may update the image processing algorithm.

For example, if 500 or more image frames in which grayscale ratios are greater than or equal to 19% are identified among a plurality of image frames included in an image signal, the at least one processor 140 may update the image processing algorithm.

For example, the at least one processor 140 may identify whether to perform update based on version information of the image processing algorithm. As an example, the at least one processor 140 may transmit version information of the image processing algorithm to an external device (e.g., a server), and if an image processing algorithm corresponding to more recent version information than the version information transmitted by the display device 100 is identified through the external device, the at least one processor 140 may update the image processing algorithm by receiving the image processing algorithm corresponding to the recent version information.

According to one or more embodiments, the updated image processing algorithm may recognize a color space of an image signal as RGB, and obtain a screen corresponding to the image signal including an RGB signal. According to one or more embodiments, the at least one processor 140 may reobtain a screen corresponding to the image signal by converting the color format of the image signal into an RGB signal by using the updated image processing algorithm, and the reobtained screen may be a normal screen (e.g., a screen in which a grayscale ratio is smaller than the threshold).

FIG. 5 is a diagram for illustrating a grayscale ratio according to an image processing algorithm according to one or more embodiments of the present disclosure.

According to one or more embodiments, an image processing algorithm may recognize a color space of an image signal as YCbCr, and obtain a screen corresponding to the image signal including a YCbCr signal. According to one or more embodiments, if the image signal includes a YCbCr signal, a screen that the at least one processor 140 obtained by converting the color format of the image signal into a YCbCr signal by using the image processing algorithm may be a normal screen.

As illustrated in the upper graph in FIG. 5, the image signal may include a plurality of image frames, and if the image processing algorithm recognizes a color space of the image signal appropriately, the grayscale ratios of each of the plurality of image frames included in the image signal may be smaller than the threshold.

According to another embodiment, the image processing algorithm may recognize a color space of an image signal as RGB, and obtain a screen corresponding to the image signal including an RGB signal. For example, if the image signal includes a YCbCr signal, a screen that the at least one processor 140 obtained by converting the color format of the image signal into an RGB signal by using the image processing algorithm may be an abnormal screen. As illustrated in the lower graph in FIG. 5, if the image processing algorithm cannot recognize a color space of the image signal appropriately, the grayscale ratios of each of the plurality of image frames may be greater than or equal to the threshold.

According to one or more embodiments, if image frames in which grayscale ratios are greater than or equal to the threshold are identified in greater than or equal to the threshold number among a plurality of image frames included in an image signal, the at least one processor 140 may update the image processing algorithm.

According to one or more embodiments, the updated image processing algorithm may recognize a color space of an image signal as YCbCr, and obtain a screen corresponding to the image signal including a YCbCr signal. According to one or more embodiments, the at least one processor 140 may reobtain a screen corresponding to the image signal by converting the color format of the image signal into a YCbCr signal by using the updated image processing algorithm, and the reobtained screen may be a normal screen (e.g., a screen in which a grayscale ratio is smaller than the threshold).

According to one or more embodiments, the at least one processor 140 may reobtain a screen in which at least one of color balance, brightness, contrast, or white balance was adjusted by using the updated image processing algorithm.

In the aforementioned embodiments, at least one processor 140 that identifies whether a grayscale ratio is greater than or equal to a threshold, and if the grayscale ratio is greater than or equal to the threshold, updates the image processing algorithm was assumed, for the convenience of explanation, but the present disclosure is obviously not limited thereto.

For example, the at least one processor 140 can obviously update the image processing algorithm if the brightness (or, the contrast, the white balance (or, the color temperature), etc.) of the screen is smaller than or equal to threshold brightness (or, reference brightness) or is greater than or equal to the threshold brightness.

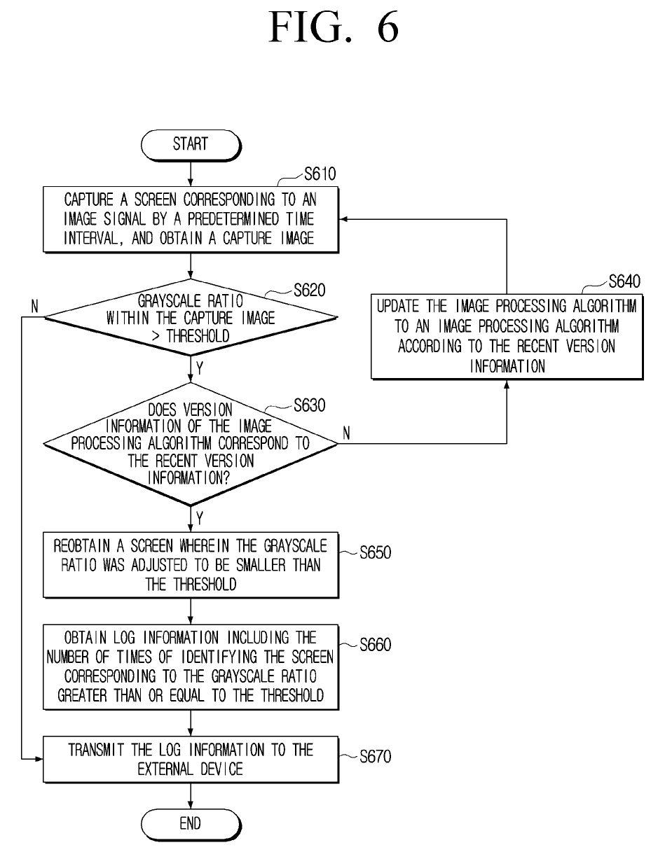

FIG. 6 is a flow chart for illustrating a control method of a display device updating an image processing algorithm according to one or more embodiments of the present disclosure.

Referring to FIG. 6, the at least one processor 140 according to one or more embodiments captures a screen corresponding to an image signal by a predetermined time interval (or, in real time), and obtains a capture image in the step S610.

If a grayscale ratio within the capture image is greater than or equal to a threshold in the step S620:Y, the at least one processor 140 identifies whether to perform update based on version information of the image processing algorithm in the step S630.

According to one or more embodiments, if relatively more recent version information than the version information is identified through an external device in the step S630:N, the at least one processor 140 may update the image processing algorithm to an image processing algorithm according to the recent version information in the step S640.

The at least one processor 140 may reobtain a screen in which the grayscale ratio was adjusted to be smaller than the threshold in the step S650 by using the updated image processing algorithm in the step S640:Y.

According to one or more embodiments, the at least one processor 140 may obtain log information including the number of times of identifying the screen corresponding to the grayscale ratio greater than or equal to the threshold in the step S660, and transmit the log information to the external device in the step S670.

According to one or more embodiments, the number of times of identification included in the log information may mean the number of times that an abnormal screen was identified (or, the number of times of generation of a defective screen), etc.

According to one or more embodiments, in the step S660, if the grayscale ratio within the screen is greater than or equal to the threshold, the at least one processor 140 may transmit the log information including state information of the display device 100 to the external device.

The state information according to one or more embodiments may include at least one of the image signal, version information of the image processing algorithm, or a set value related to image output of the display device 100.

According to one or more embodiments, the set value related to image output of the display device 100 may include set values corresponding to each of hues, saturation, and lightness, and set values corresponding to each of brightness, contrast, white balance, luminance, and gamma. However, this is merely an example, and the present disclosure is obviously not limited thereto. For example, the set value related to image output can obviously include a refresh rate, an operation mode (e.g., a game mode, a cinema mode, etc.), HDR ON/OFF, a communication format of receiving an image signal (e.g., an HDMI, a DP, etc.), and the like.

According to one or more embodiments, based on the state information including the set value related to image output, the display device 100 can easily reproduce a situation in which an abnormal screen is obtained (or, a situation in which distortion is generated), and there is an effect that a situation in which a defective screen is output is reproduced at the time of repair of the display device 100, and the cause of the defect can thereby be figured out easily.

Also, by using the state information including the set value related to image output, the display device 100 can obtain a database (DB) regarding a situation in which an abnormal screen is obtained, and the display device 100 can improve the image processing algorithm based on the obtained database (DB).

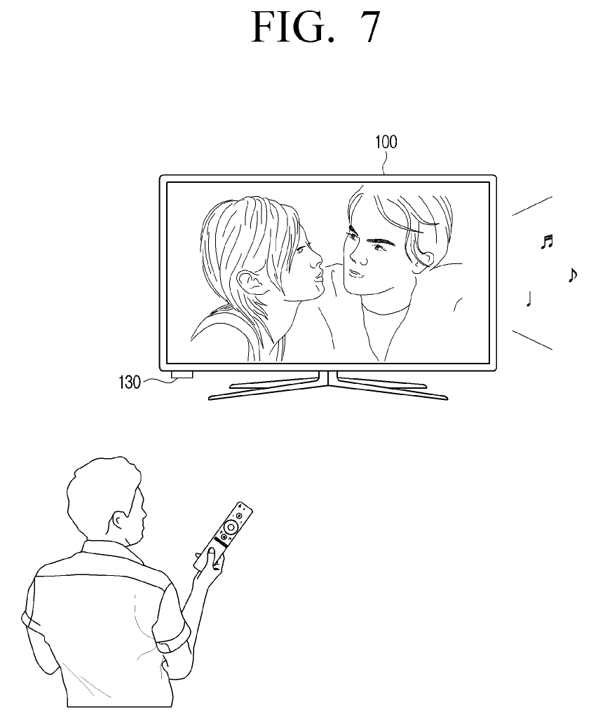

FIG. 7 is a diagram for illustrating a display device outputting a sound according to one or more embodiments of the present disclosure.

The display device 100 according to one or more embodiments of the present disclosure may further include a speaker and a microphone.

The speaker according to one or more embodiments may output a sound corresponding to an audio signal. The speaker may include at least one speaker unit (or an audio amplifier).

According to one or more embodiments, the speaker may be implemented as at least one full range speaker designed to output almost all vocal ranges of audible frequencies.

According to one or more embodiments, the speaker may include a plurality of speakers for reproduction of multi channels. For example, the speaker may include a plurality of speakers that are in charge of each channel that is mixed and output. Depending on cases, it is also possible that a speaker in charge of at least one channel is implemented as a speaker array including a plurality of speaker units for reproducing different frequency bands.

The at least one processor 140 according to one or more embodiments may, if an audio signal is included in an image signal, control the speaker to output a sound corresponding to the audio signal.

The microphone according to one or more embodiments is a component for receiving a sound output by the display device 100 and converting it into an electric signal. According to one or more embodiments, the microphone may be provided on a lower side of a side surface of the display device 100, etc. The microphone according to one or more embodiments may receive a sound output by the display device 100 and transmit it to the at least one processor 140.

However, this is merely an example for the convenience of explanation, and a remote control device 200 that transmits a control signal to the display device 100 may include a microphone, and the microphone provided on the remote control device 200 may receive a sound output by the display device 100 and convert it into an electric signal. According to one or more embodiments, the remote control device 200 may receive a sound through the microphone provided on the remote control device 200, and transmit it to the display device 100.

According to one or more embodiments, the at least one processor 140 may identify whether a sound was received through the microphone.

For example, if a sound output by the speaker is received through the microphone, the at least one processor 140 may identify that a sound corresponding to an audio signal is output normally. According to one or more embodiments, if a sound output by the speaker is not received through the microphone, the at least one processor 140 may identify that a sound corresponding to an audio signal is not output normally.

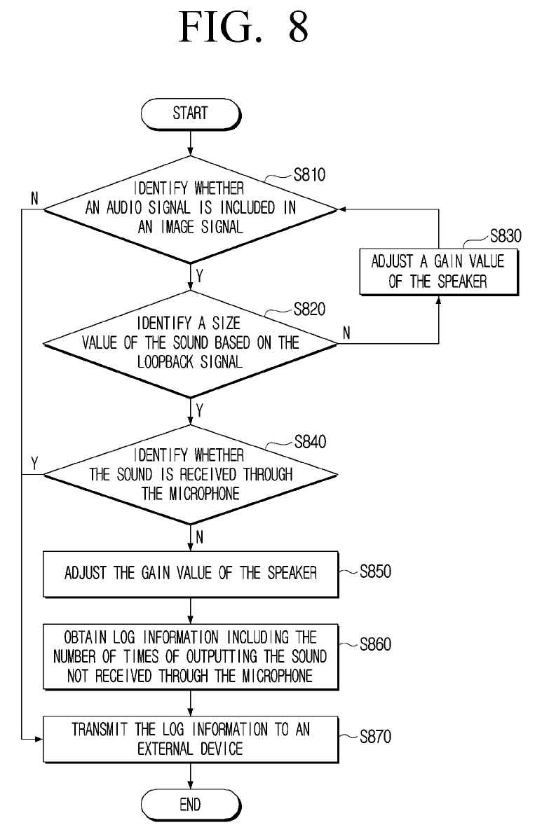

FIG. 8 is a flow chart for illustrating a control method of a display device adjusting a gain of a speaker according to one or more embodiments of the present disclosure.

Referring to FIG. 8, the at least one processor 140 may identify whether an audio signal is included in an image signal in the step S810.

According to one or more embodiments, if an audio signal is identified in the step S810:Y, the at least one processor 140 may receive a loopback signal according to output of a sound through the speaker.

The loopback signal according to one or more embodiments may be a signal that is generated when the at least one processor 140 transmits an audio signal to the speaker, and the speaker receives the audio signal from the at least one processor 140.

According to one or more embodiments, the at least one processor 140 may identify whether the speaker operates normally based on the loopback signal.

For example, the at least one processor 140 may identify a size value of the sound based on the loopback signal in the step S820. For example, the at least one processor 140 may identify transmission of an audio signal, and whether a loopback signal generated by reception of the audio signal by the speaker includes a decibel (dB) value of the sound.

According to one or more embodiments, if the size value (e.g., the dB value) of the sound is not identified based on the loopback signal in the step S820:N, the at least one processor 140 may identify an abnormal operation of the speaker or a state in which a sound is not output.

According to one or more embodiments, if the size value of the sound is not identified based on the loopback signal in the step S820:N, the at least one processor 140 may adjust a gain value of the speaker in the step S830. For example, the at least one processor 140 may adjust an audio amplifier (amp) gain value of the speaker. For example, the at least one processor 140 may increase a volume of a sound output by the speaker by increasing the gain value.

According to one or more embodiments, if the size value of the sound is identified based on the loopback signal in the step S820:Y, the at least one processor 140 may identify whether the sound is received through the microphone in the step S840.

For example, if the sound is not received through the microphone in the step S840:N, the at least one processor 140 may adjust the gain value of the speaker in the step S850. For example, the at least one processor 140 may adjust a gain value of an IC chip inside the audio amplifier (amp) of the speaker.

According to one or more embodiments, the at least one processor 140 may obtain log information including the number of times of outputting the sound not received through the microphone in the step S860, and transmit the log information to an external device in the step S870.

According to one or more embodiments, the number of times of identification included in the log information may mean the number of times that the speaker operated abnormally or the number of times of generation of a state in which the sound was not output (or, the number of times of output of a defective sound), etc.

According to one or more embodiments, in the step S860, if the sound corresponding to the audio signal is not received through the microphone, the at least one processor 140 may transmit the log information including the state information of the display device 100 to the external device.

The state information according to one or more embodiments may include at least one of the audio signal, the gain value of the speaker, or a set value related to sound output of the display device 100.

According to one or more embodiments, the set value related to sound output of the display device 100 may include set values corresponding to each of a sound volume corresponding to the setting of the user, left/right channel balance, the strength of the reverb effector, and the equalizer. However, this is merely an example, and the present disclosure is obviously not limited thereto. For example, the set value related to sound output can obviously include channel information (e.g., a 2.1 channel, a 5.1 channel), an operation mode (e.g., a classical mode, a rock concert mode, etc.), a communication format of receiving an audio signal (e.g., an HDMI, USB-C, Bluetooth, etc.), and the like.

According to one or more embodiments, based on the state information including the set value related to sound output, the display device 100 can easily reproduce a situation in which the speaker operates abnormally (or, a situation in which distortion is generated, a situation in which a sound is not output), and there is an effect that a situation in which the speaker operates abnormally is reproduced at the time of repair of the display device 100, and the cause of the defect can thereby be figured out easily.

Also, by using the state information including the set value related to sound output, a database (DB) regarding a situation in which the display device 100 does not output a sound can be obtained, and the gain value of the speaker can be adjusted appropriately, or the set value related to sound output can be adjusted appropriately based on the obtained database (DB).

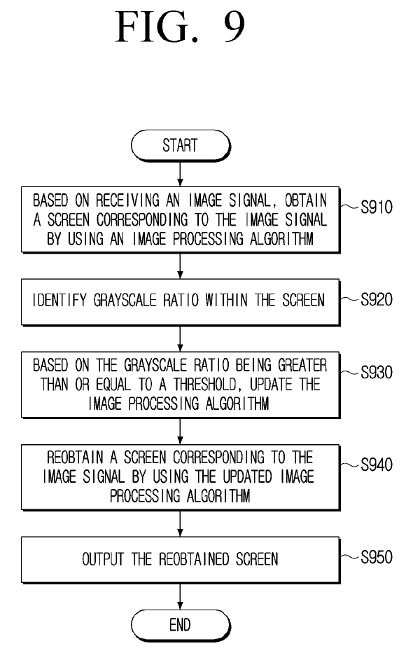

FIG. 9 is a flow chart for illustrating a control method of a display device according to one or more embodiments of the present disclosure.

In a control method of a display device according to one or more embodiments of the present disclosure, first, based on receiving an image signal, a screen corresponding to the image signal is obtained by using an image processing algorithm in the step S910.

A grayscale ratio within the screen is identified in the step S920.

Based on the grayscale ratio being greater than or equal to a threshold, the image processing algorithm is updated in the step S930.

A screen corresponding to the image signal is reobtained by using the updated image processing algorithm in the step S940.

The reobtained screen is output in the step S950.

The control method according to one or more embodiments further includes the step S960 of, based on the grayscale ratio within the screen being greater than or equal to the threshold, transmitting log information including state information of the display device to an external device.

The step S930 of updating according to one or more embodiments may include the step of, based on the grayscale ratio being greater than or equal to the threshold, identifying whether to perform update based on version information of the image processing algorithm, and the step S940 of reobtaining may include the step of reobtaining the screen in which the grayscale ratio was adjusted by using the updated image processing algorithm.

The step S940 of reobtaining according to one or more embodiments may include the step of reobtaining the screen in which at least one of color balance, brightness, contrast, or white balance was adjusted by using the updated image processing algorithm.

The log information according to one or more embodiments may include the number of times of identifying the screen corresponding to the grayscale ratio greater than or equal to the threshold, and the state information may include at least one of the image signal, version information of the image processing algorithm, or a set value related to image output of the display device.

The step S910 of obtaining according to one or more embodiments may include the step of obtaining the screen corresponding to the image signal by converting a color format of the image signal into an RGB signal using the image processing algorithm, and the step S940 of reobtaining may include the step of reobtaining the screen corresponding to the image signal by converting the color format of the image signal into a YCbCr signal using the updated image processing algorithm.

The step S910 of obtaining according to one or more embodiments may include the step of obtaining the screen corresponding to the image signal by converting a color format of the image signal into a YCbCr signal using the image processing algorithm, and the step S940 of reobtaining may include the step of reobtaining the screen corresponding to the image signal by converting the color format of the image signal into an RGB signal using the updated image processing algorithm.

The control method according to one or more embodiments may further include the steps of, based on the image signal including an audio signal, outputting a sound corresponding to the audio signal through a speaker included in the display device, and identifying whether the sound was received through a microphone included in the display device.

The control method according to one or more embodiments may further include the steps of, based on the sound not being received through the microphone, adjusting a gain value of the speaker, and re-outputting the sound corresponding to the audio signal through the microphone in which the gain value was adjusted.

The control method according to one or more embodiments may further include the steps of receiving a loopback signal according to the output of the sound through the speaker, and based on a size value of the sound not being identified based on the loopback signal, adjusting a gain value of the speaker.

The control method according to one or more embodiments may further include the step of, based on the sound not being received through the microphone, transmitting the log information including the state information of the display device to the external device, and the log information may include the number of times of outputting the sound that was not received through the microphone, and the state information may include at least one of the audio signal, the gain value of the speaker, or a set value related to sound output of the display device.

The various embodiments of the present disclosure can not only be applied to a display device, but also to various types of electronic apparatuses including a display function.

The aforementioned various embodiments may be implemented in a recording medium that can be read by a computer or an apparatus similar to a computer, by using software, hardware, or a combination thereof. In some cases, the embodiments described in this specification may be implemented as a processor itself. According to implementation by software, the embodiments such as procedures and functions described in this specification may be implemented as separate software modules. Each of the software modules can perform one or more functions and operations described in this specification.

Computer instructions for performing processing operations of the display device 100 according to the aforementioned various embodiments of the present disclosure may be stored in a non-transitory computer-readable medium. Computer instructions stored in such a non-transitory computer-readable medium make the processing operations at the display device 100 according to the aforementioned various embodiments performed by a specific machine, when the instructions are executed by the processor of the specific machine.

A non-transitory computer-readable medium refers to a medium that stores data semi-permanently, and is readable by machines, but not a medium that stores data for a short moment such as a register, a cache, and memory. As specific examples of a non-transitory computer-readable medium, there may be a CD, a DVD, a hard disc, a blue-ray disc, a USB, a memory card, ROM and the like.

Also, while example embodiments of the present disclosure have been shown and described, the present disclosure is not limited to the aforementioned specific embodiments, and it is apparent that various modifications may be made by those having ordinary skill in the technical field to which the present disclosure belongs, without departing from the gist of the present disclosure as claimed by the appended claims. Further, it is intended that such modifications are not to be interpreted independently from the technical idea or prospect of the present disclosure.

What is claimed is:

1. A display device comprising:
a communication interface;
a display;
memory storing instructions; and
at least one processor,
wherein the instructions, when executed by the at least one processor individually or collectively, cause the display device to:
based on receiving an image signal, obtain a screen corresponding to the image signal by using an image processing algorithm,
identify a grayscale ratio within the screen,
based on the grayscale ratio being greater than or equal to a threshold, update the image processing algorithm,
reobtain a screen corresponding to the image signal by using the updated image processing algorithm,
control the display to output the reobtained screen, and
based on the grayscale ratio within the screen being greater than or equal to the threshold, control the communication interface to transmit log information comprising state information of the display device to an external device.

2. The display device of claim 1, wherein the instructions, when executed by the at least one processor individually or collectively, cause the display device to:
based on the grayscale ratio being greater than or equal to the threshold, identify whether update was performed based on version information of the image processing algorithm, and
reobtain the screen in which the grayscale ratio was adjusted by using the updated image processing algorithm.

3. The display device of claim 2, wherein the instructions, when executed by the at least one processor individually or collectively, cause the display device to:
reobtain the screen in which at least one of color balance, brightness, contrast, or white balance was adjusted by using the updated image processing algorithm.

4. The display device of claim 1, wherein the log information comprises a number of times that the grayscale ratio of the screen is identified to be greater than or equal to the threshold, and
wherein the state information comprises at least one of the image signal, version information of the image processing algorithm, or a set value related to image output of the display device.

5. The display device of claim 1, wherein the instructions, when executed by the at least one processor individually or collectively, cause the display device to:
obtain, using the image processing algorithm, the screen corresponding to the image signal by converting a color format of the image signal into an RGB signal; and
reobtain, using the updated image processing algorithm, the screen corresponding to the image signal by converting the color format of the image signal into a YCbCr signal.

6. The display device of claim 1, wherein the instructions, when executed by the at least one processor individually or collectively, cause the display device to:
obtain, using the image processing algorithm, the screen corresponding to the image signal by converting a color format of the image signal into a YCbCr signal; and
reobtain, using the updated image processing algorithm, the screen corresponding to the image signal by converting the color format of the image signal into an RGB signal.

7. The display device of claim 1, further comprising:
a speaker; and
a microphone,
wherein the instructions, when executed by the at least one processor individually or collectively, cause the display device to:
based on the image signal comprising an audio signal, output a sound corresponding to the audio signal through the speaker; and
identify whether the sound was received through the microphone.

8. The display device of claim 7, wherein the instructions, when executed by the at least one processor individually or collectively, cause the display device to:
based on the sound not being received through the microphone, adjust a gain value of the speaker; and
re-output the sound corresponding to the audio signal through the microphone in which the gain value was adjusted.

9. The display device of claim 7, wherein the instructions, when executed by the at least one processor individually or collectively, cause the display device to:
receive a loopback signal according to the output of the sound through the speaker; and
based on a size value of the sound not being identified based on the loopback signal, adjust a gain value of the speaker.

10. The display device of claim 7, wherein the instructions, when executed by the at least one processor individually or collectively, cause the display device to:
based on the sound not being received through the microphone, transmit the log information comprising the state information of the display device to the external device,
wherein the log information comprises a number of times of outputting the sound that was not received through the microphone, and
wherein the state information comprises at least one of the audio signal, a gain value of the speaker, or a set value related to sound output of the display device.

11. A method of controlling a display device, the method comprising:
based on receiving an image signal, obtaining a screen corresponding to the image signal by using an image processing algorithm;
identifying a grayscale ratio within the screen;
based on the grayscale ratio being greater than or equal to a threshold, updating the image processing algorithm;
reobtaining a screen corresponding to the image signal by using the updated image processing algorithm;
outputting the reobtained screen; and
based on the grayscale ratio within the screen being greater than or equal to the threshold, transmitting log information including state information of the display device to an external device.

12. The method of claim 11, wherein the updating comprises, based on the grayscale ratio being greater than or equal to the threshold, identifying whether update was performed based on version information of the image processing algorithm, and
wherein the reobtaining comprises reobtaining the screen in which the grayscale ratio was adjusted using the updated image processing algorithm.

13. The method of claim 12, wherein the reobtaining comprises reobtaining the screen in which at least one of color balance, brightness, contrast, or white balance was adjusted using the updated image processing algorithm.

14. The method of claim 11, wherein the log information includes a number of times that the grayscale ratio of the screen is identified to be greater than or equal to the threshold, and
wherein the state information comprises at least one of the image signal, version information of the image processing algorithm, or a set value related to image output of the display device.

15. The method of claim 14, wherein the obtaining comprises obtaining, using the image processing algorithm, the screen corresponding to the image signal by converting a color format of the image signal into an RGB signal; and
wherein the reobtaining comprises, using the updated image processing algorithm, reobtaining the screen corresponding to the image signal by converting the color format of the image signal into a YCbCr signal.

16. The method of claim 11, wherein the reobtaining comprises obtaining, the image processing algorithm, the screen corresponding to the image signal by converting a color format of the image signal into a YCbCr signal; and
wherein the reobtaining comprises reobtaining, using the updated image processing algorithm, the screen corresponding to the image signal by converting the color format of the image signal into an RGB signal.

17. The method of claim 11, the method further comprises;
based on the image signal comprising an audio signal, outputting a sound corresponding to the audio signal through a speaker; and
identifying whether the sound was received through a microphone.

18. The method of claim 17, the method further comprises;
based on the sound not being received through the microphone, adjusting a gain value of the speaker; and
re-outputting the sound corresponding to the audio signal through the microphone in which the gain value was adjusted.

19. The method of claim 17, the method further comprises;
receiving a loopback signal according to the output of the sound through the speaker; and
based on a size value of the sound not being identified based on the loopback signal, adjusting a gain value of the speaker.

20. A non-transitory computer-readable medium storing a computer instruction, which when executed by at least one processor of a display device causes the electronic device to control the display device comprising:
based on receiving an image signal, obtaining a screen corresponding to the image signal by using an image processing algorithm;
identifying a grayscale ratio within the screen;
based on the grayscale ratio being greater than or equal to a threshold, updating the image processing algorithm;
reobtaining a screen corresponding to the image signal by using the updated image processing algorithm;
outputting the reobtained screen; and
based on the grayscale ratio within the screen being greater than or equal to the threshold, transmitting log information including state information of the display device to an external device.
